(19) United States
(12) Patent Application Publication
(10) Pub. No.: US 2015/0012249 A1
(43) Pub. Date: Jan. 8, 2015

(54) Minute Signal Detection Method and System

(71) Applicant: Hitachi Ltd., Chiyoda-ku, Tokyo (JP)

(72) Inventors: Wen Li, Tokyo (JP); Hisaaki Kanai, Tokyo (JP); Yutaka Uematsu, Tokyo (JP); Masami Makuuchi, Tokyo (JP)

(21) Appl. No.: 14/378,227

(22) PCT Filed: Jan. 21, 2013
(86) PCT No.: PCT/JP2013/051030

§ 371 Date: Aug. 12, 2014

(30) Foreign Application Priority Data
Feb. 17, 2012 (JP) 2012-032305

(51) Int. Cl. H04B 1/10; G01R 29/26

(52) U.S. Cl. CPC H04B 1/1027; G01R 29/26
USPC 702/191

(57) ABSTRACT

In an environment in which signal-to-noise is poor, a method and a system configuration for power-saving, low-cost, and general minute signal detection are provided. The system includes a circuit that converts and amplifies an input signal, a nonlinear analog front-end circuit that determines the existence of a minute signal from the input signal and that outputs information on the existence of the same as an event signal, an analog-to-digital-conversion circuit that drives operation-mode control based on the event signal and performs analog-to-digital conversion on the converted-and-amplified input signal, a data-transfer circuit that drives the operation-mode control by the event signal and transfers the analog-to-digital converted signal, a digital-signal-processing circuit that drives the operation-mode control by the event signal and performs digital-signal processing on the signal transmitted from the data-transfer circuit and detects the signal, and a parameter-control circuit that controls a characteristic parameter of the nonlinear analog front-end circuit.

### TECHNICAL FIELD

The present invention relates to a method and system of detecting a minute signal.

### BACKGROUND ART

As a signal detection method and system in the related art, to detect a signal from noise, the noise level is reduced by data processing such as spatial or temporal averaging addition, the signal-to-noise ratio is improved and a minute signal is detected example, a semiconductor inspection/measurement apparatus is an apparatus that emits a laser, light or electron beam to a wafer of the measurement and inspection target, generates measurement and detection signals from generated scattered light and secondary electrons, and performs measurement and inspection based on the measurement and detection signals. In a case where semiconductor manufacturing is inspected using this semiconductor inspection/measurement apparatus, since the generation of malfunction and failure in a manufacturing process is detected early or beforehand, pattern measurement and inspection on a semiconductor wafer are performed at the end of each manufacturing process. A signal detection system of the semiconductor inspection/measurement apparatus includes a detector that detects light and electronic signals generally generated from an inspection target and a circuit that converts, amplifies and processes the signals into electrical signals. Various noises enter these detector and detection circuit, and these noises are generally random noises. To sensitively detect valid signals, for example, noise randomness is used to perform averaging processing. For example, PTL 1 describes “a signal that responds to a certain input signal is assumed to be a detection target, and especially in a multichannel feeble signal detection system that detects multiple response signals that change over time, minute signals are detected at a high SN ratio by performing time division multiplexing on she input signal, optimizing multiplexing conditions and performing two-stage averaging processing on the response signal” (see PTL 1).

### CITATION LIST

### Patent Literature

PTL 1: JP 2008-286736 A

### SUMMARY OF INVENTION

### Technical Problem

However, along with the miniaturization of a semiconductor process in recent years, a sensor output signal of an inspection measurement apparatus has become small, and the signal-to-noise ratio (SNR) becomes equal to or less than 1 that is a signal detection limit. To reduce noise by a large amount of addition channels to detect a signal whose SNR is equal to or less than 1 requires large physical size restriction and a huge cost, which realistically difficult.

To realize high performance, high throughput and portability in medical apparatuses and analysis apparatuses, there is a growing demand for a detection technique of minute signals whose SNR is equal to or less than 1. Further, even in the field of health care, body implanted devices and biomedical signal application devices, and so on, that achieve a high level of growth at present, the use in a poor noise environment and the exchange of minute signals for power saving are required. Even in these signal detection systems, in a multichannel addition scheme and a long time average calculation scheme in the related art, a large amount of processing data leads to the increasing size, an increase in costs and an increase in power consumption, and it is difficult to realize low cost, power saving and miniaturization.

The present invention is made in view of such a situation, and there is provided a minute signal detection method that solves the above-mentioned problem and a system that realizes it.

### Solution to Problem

To solve the above-mentioned problem, the configurations described in the claims are adopted. For example, a minute signal detection system according to the present invention includes: a circuit which converts and amplifies an input signal; a nonlinear analog front-end circuit which determines an existence/nonexistence of a minute signal from the input signal converted and amplified by the amplification circuit and which outputs information on the existence/nonexistence of the minute signal as an event signal; an analog-to-digital conversion circuit which drives operation mode control based on the event signal output by the nonlinear analog front-end circuit and performs analog-to-digital conversion on the converted, amplified input signal; a data transfer circuit which drives the operation mode control by the event, signal and transfers the signal subjected to the analog-to-digital conversion; a digital signal processing circuit which drives the operation mode control by the event signal and performs digital signal processing on the signal transmitted from the data transfer circuit and detects the signal; and a parameter control circuit which controls a characteristic parameter of the nonlinear analog front-end circuit according to characteristics of the minute signal and a noise.

### Advantageous Effects of Invention

According to the present invention, it is possible to realize, a minute signal detection method and system that enables low cost, power saving and miniaturization.

### BRIEF DESCRIPTION OF DRAWINGS

FIG. 1 is a diagram illustrating a schematic configuration of a minute signal detection system.

FIG. 2 is a diagram illustrating a schematic configuration of a minute signal detection system according to an embodiment of the present invention.

FIG. 3 is a diagram illustrating the outline of bistable system circuit realization according to an embodiment of the present invention.

FIG. 4 is a system configuration diagram of minute signal detection simulation of a low signal-to-noise ratio according to an embodiment of the present invention.

FIGS. 5(a) to 5(c) are diagrams illustrating simulation results of minute signal detection of a low signal-to-noise ratio according to an embodiment of the present invention.

FIG. 6 is a conceptual diagram of a bistable system.

FIG. 7 is a physical image of stochastic resonance.

FIG. 8 is a diagram illustrating a schematic configuration of a general parallel, processing minute signal detection system.

FIG. 9 is a diagram illustrating a schematic configuration of a minute signal detection system according to a second embodiment.

FIG. 10 is a diagram illustrating a circuit configuration of an advanced bistable system that can improve the signal detection rate even in a case where a parameter is not an optimum value in a bistable system.

FIG. 11 is a diagram illustrating one example of a circuit configuration a reset signal generation unit.

FIG. 12 is a diagram illustrating one example of a circuit configuration of a signal shaping unit.

FIG. 13 is a diagram illustrating a circuit configuration of an advanced bistable system that applies a low-pass filter and a comparator.

FIG. 14 is a diagram illustrating a simulation result of minute signal detection of a low signal-to-noise ratio in a case where a system parameter becomes out of an optimum value in a bistable system.

FIG. 15 is a diagram illustrating a simulation result of minute signal detection of a low signal-to-noise ratio in a case where an advanced bistable system is applied.

FIG. 16 illustrates a relationship between a system parameter and a signal detection rate.

### DESCRIPTION OF EMBODIMENTS

In the following, an embodiment of the present invention is described with reference to the accompanying drawings. In the accompanying drawings, functionally identical components may be displayed with the identical number. Here, although the accompanying drawings show specific embodiments and implementation examples according to the principle of the present invention, these are provided for the understanding of the present invention and are not used to interpret the present invention in a limited way.

In the present embodiment, although sufficiently detailed explanation required for those skilled in the art to implement the present invention is given, other implementations and modes are possible, and it is necessary to understand that configurations/structures can be changed and various components can be replaced without departing from the scope and spirit of the technical idea of the present invention. Therefore, the following description should not be limited to this and interpreted.

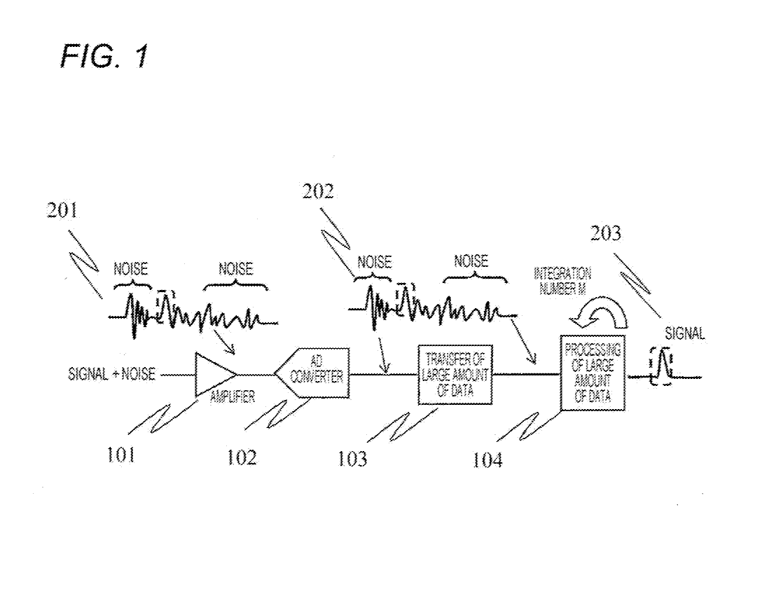

First, a configuration of a general minute signal detection system is described. FIG. 1 is a diagram illustrating the configuration of the general signal detection system. A signal conversion/amplification circuit 101 converts an input signal 201 (signal including noise) into a necessary physical quantity, for example, converts it from the current to the voltage, and amplifies it to the level required in subsequent processing. An analog-to-digital signal conversion circuit 102 converts the amplified analog signal into a digital signal and inputs it in a high-performance digital signal processing circuit 104 via a data transfer circuit 103. Using various signal processing techniques, the digital signal processing circuit 104 separates/detects a valid signal from the signal including noise.

Without signals, background noise always exists in the case of systems/apparatuses such as a malfunction monitoring system for industrial society, a semiconductor defect/foreign-body inspection apparatus, a medical apparatus and a biomedical signal monitoring apparatus in a case where the signal-to-noise ratio (SNR) is low or especially in the case of SNR<1, to transfer and process a large amount of data like filtering and integration processing is always necessary in order to detect a signal from noise.

For example, like the technique shown in PTL 1, with respect to a periodic signal, data per signal period is divided into frames on the time axis, random noise is reduced by frame addition, and the signal-to-noise ratio is improved to perform signal detection.

Generally, in the case of Gaussian distribution random noise, there is a relationship of M=K̂2 between magnification K to improve the SNR and addition processing number M. For example, to make the SNR required for signal detection in an inspection apparatus equal to or greater than 6, 36 times of addition are necessary in a case where the SNR is 1.

Meanwhile, in a case where the SNR is 0.5, the addition number becomes 144. When the SNR is deteriorated up to 0.2, the necessary addition number becomes large up to 900. For detection of signals of such a low signal-to-noise ratio, it is difficult to realize a detection scheme in the related art illustrated in FIG. 1 at low cost with power saving.

### First Embodiment

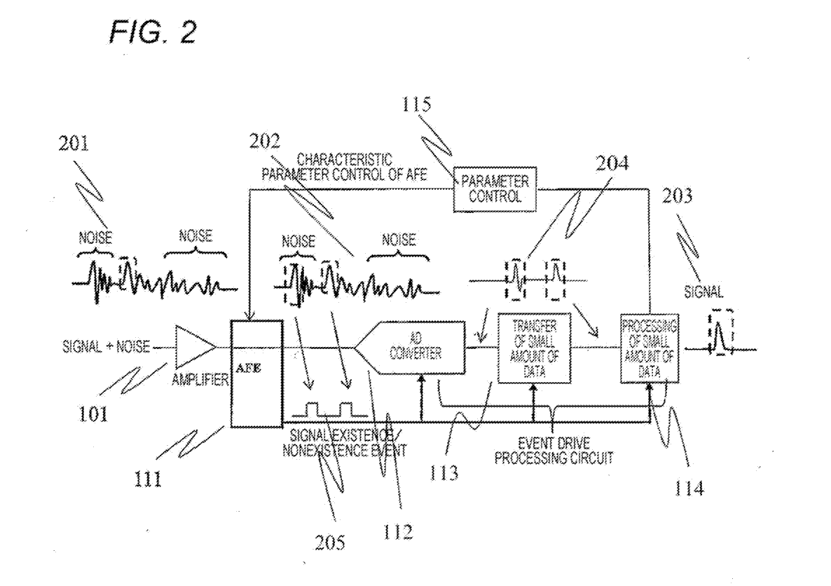

FIG. 2 is a diagram illustrating a configuration of a minute signal detection system according to the first embodiment of the present invention. When the configuration in FIG. 2 is adopted, it is possible to detect a minute signal in a low-cost, power-saving system configuration even in an environment in which the signal-to-noise ratio (SNR) is deteriorated.

As illustrated in FIG. 2, the minute signal detection system includes the signal conversion/amplification circuit 101 that converts and amplifies a minute signal, which is a signal embedded in noise and in which the signal-to-noise ratio is lowered by the noise, into a necessary physical quantity, a nonlinear system analog front-end (AFE) circuit 111 that can detect whether there is a minute signal embedded in the noise, an analog-to-digital signal converter 112, a data transfer circuit 113, a digital signal processing circuit 114 and a parameter control circuit 115 that performs optimization control of characteristic parameters of the analog front-end circuit 111.

When the input signal 201 including a minute signal embedded in noise is input in the analog front-end circuit the analog front-end circuit 111 detects an existence/nonexistence state of the minute signal with respect to the input signal at a high probability by parameter optimization of the analog front-end circuit.

Further, after the existence/nonexistence of the minute signal is detected, an event signal 205 including minute signal existence/nonexistence information is output from the analog front-end circuit 111 on the basis of the detection result, and this even signal 205 is input in the analog-to-digital signal conversion circuit 112, the data signal transfer circuit 113 and the digital signal processing circuit 114 in subsequent stages. The analog-to-digital signal conversion circuit 112, the data transfer circuit 113 and the digital signal processing circuit 114 are basically event drive processing circuits, and the operation mode of these circuits is controlled by the signal existence/nonexistence information included in the event signal 205.

When the event signal 205 is signal nonexistence information, the analog-to-digital signal conversion circuit 112, the data transfer circuit 113 and the digital signal processing circuit 114 enter a pause mode or power saving mode state to reduce the power consumption.

When the event signal 205 is signal existence information, the analog-to-digital signal conversion circuit 112, the data transfer circuit 113 and the digital signal processing circuit 114 are switched to an operation mode to detect the minute signal by performing analog-to-digital conversion, necessary minimum data transfer and signal processing on an input signal 202 processed in the signal conversion/amplification circuit 101.

To realize the minute signal detection system of the present embodiment, it is important to realize the analog front-end circuit 111 that can determine the existence/nonexistence of the minute signal embedded in the noise.

Since the signal and the noise are amplified at the same magnification in a linear analog front-end circuit, it is not effective in the improvement of the signal-to-noise ratio. Therefore, in the present invention, the above-mentioned problem is solved by adopting a nonlinear analog front-end system.

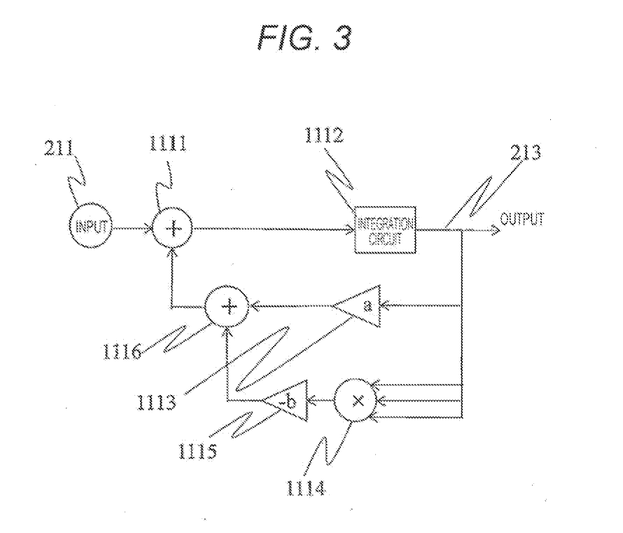

FIG. 3 illustrates a circuit configuration diagram of one embodiment of a nonlinear analog front-end circuit adopted in the present invention. The mathematical model of this analog front-end circuit is one non-linear system that exists in the natural world or the life field. The mathematical formula of this model is expressed by equation (1).

$$\frac{d {Z}_{out} ( t )}{d t} = a {Z}_{out} ( t ) - b {{Z}_{out} ( t )}^{3} + {Z}_{in} ( t ) \qquad [ Equation 1 ]$$

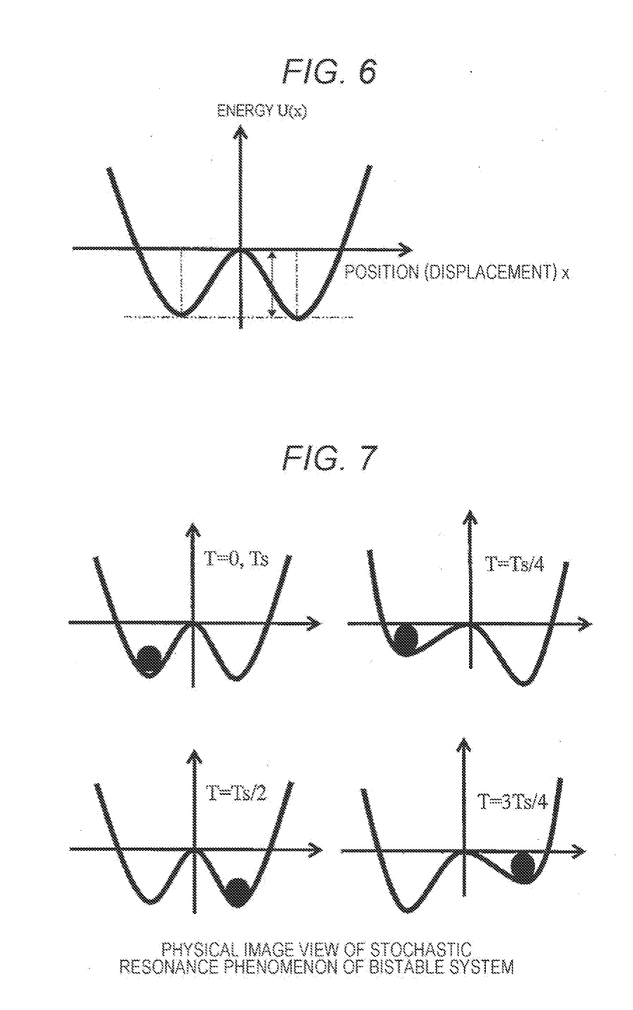

The non-linear system using the above-mentioned equation is a bistable system. The bistable system has two stable states as illustrated in FIG. 6. There is a potential wall between two stable states. In such a bistable system, there is a possibility that a stochastic resonance phenomenon occurs.

FIG. 7 illustrates a physical image of the stochastic resonance. This figure illustrates the states of a gradual tilting of the system and particle jump by noise application. It is assumed that the particle exists in the well, of one potential. The whole of this system is tilted in a slight, gradual periodic vibration.

The cycle of this tilting is illustrated in the figure. However, in this situation, the particle merely moves to the right and left in the bottom of the well of the potential. It is assumed that, when this particle comes out from the bottom of the well, the movement of this system can be detected for the first time. It is considered that, when noise is added, a slight periodic signal of this system is commonsensically concealed. However, in a case where the system is a nonlinear system, the situation is different.

Here, in the case as shown in (Equation 1), the noise and the slight periodic vibration are matched and the particle can come out. It is because the noise excites the slight periodic signal. At this time, the periodic signal and the noise resonate in a certain range of noise strength. These are a phenomenon called “stochastic resonance”, and, based on the frequency at which the particle comes out, it is possible detect the slight periodic signal and acquire the information. An important thing here is that there is a suitable threshold for the level of added noise when the stochastic resonance occurs.

In the above-mentioned system, in a case where an input signal (including noise) including a slight signal matches the system parameter of the bistable model in a correlated manner, the stochastic resonance phenomenon occurs when the stable state of the bistable system is based on a signal existence/nonexistence state. That is, the stochastic resonance phenomenon is a phenomenon in which a minute signal embedded in noise is strengthened by the level, of the noise and can be detected in a certain nonlinear system (such as a bistable system and a mono-stable system). In the present embodiment, a bistable system in which the stochastic resonance phenomenon is likely to occur is realized by the circuit configuration illustrated in FIG. 3. A basic circuit configuration of the bistable system based on (Equation 1) is a system in which the signal 213 showing information on a stable state and an output signal is fed back to an input signal in two separate ways.

The sum of the input signal and the feedback signal (feedback amount) from the output is integrated in an integration circuit 1112 to generate the output signal 213. One of feedback amounts separated in two paths is amplified by a gain a 1113. Moreover, it is configured such that the other one of the feedback amounts is amplified in a tertiary-square circuit 1114 and further amplified by a gain b 1115 and the phase is reversed.

Two feedback amounts are added in an addition circuit. 1116, further combined with the input signal in an addition circuit 1111 and input in the integration circuit 1112 that generates the output signal. By using the circuit configured as above as the analog front-end circuit of the first embodiment in FIG. 2, it is possible to detect whether there is a minute signal embedded in noise, according to the occurrence of the stochastic resonance phenomenon.

Further, after the existence/nonexistence of the minute signal is detected, the event signal 205 including minute signal existence/nonexistence information is output from the analog front-end circuit 111 on the basis of the detection result, and this even signal 205 is input in the analog-to-digital signal conversion circuit 112, the data signal transfer circuit 113 and the digital signal processing circuit 114 in subsequent stages.

The analog-to-digital signal conversion circuit 112, the data transfer circuit 113 and the digital signal processing circuit 114 are basically event drive processing circuits, and the operation mode of these circuits is controlled by the signal existence/nonexistence information included in the event signal 205.

When the event signal 205 is signal nonexistence information, the analog-to-digital signal conversion circuit 112, the data transfer circuit 113 and the digital signal processing circuit 114 enter a pause mode or power saving mode state to reduce the power consumption.

When the event signal 205 is signal existence information, the analog-to-digital signal conversion circuit 112, the data transfer circuit 113 and the digital signal processing circuit 114 are switched to an operation mode to detect the minute signal by performing analog-to-digital conversion, necessary minimum data transfer and signal processing on the input signal 202 processed in the signal conversion/amplification circuit 101.

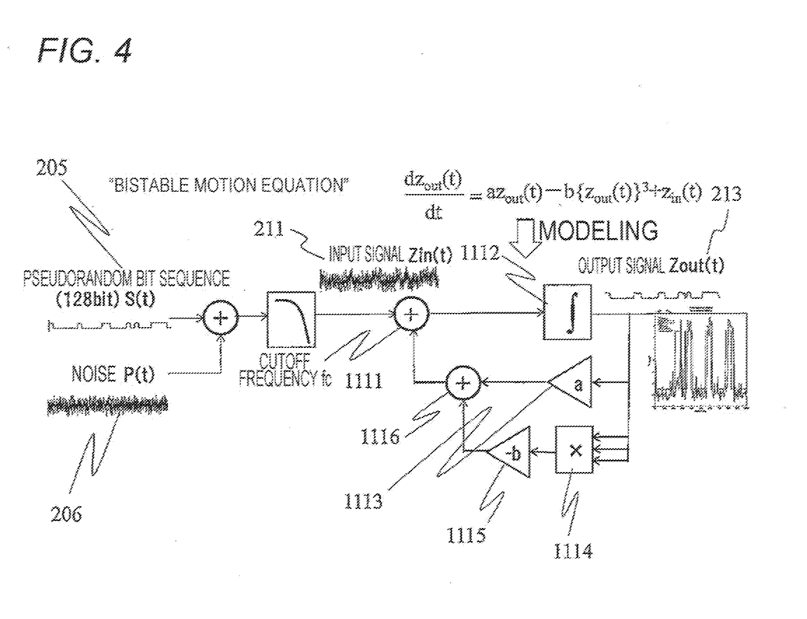

Next, a simulation result is described about a minute signal detection system by an analog front-end circuit using the above-mentioned bistable model. FIG. 4 illustrates a system configuration diagram of the simulation.

In a case where an input signal 211 formed by adding a signal 205 formed with random pulses and a random noise 206 passes a bistable circuit formed with 1111 to 1116 and a condition to cause the stochastic resonance phenomenon is satisfied, 80 percent or more minute signals are output as compared with the random pulse signal 205 in the related art.

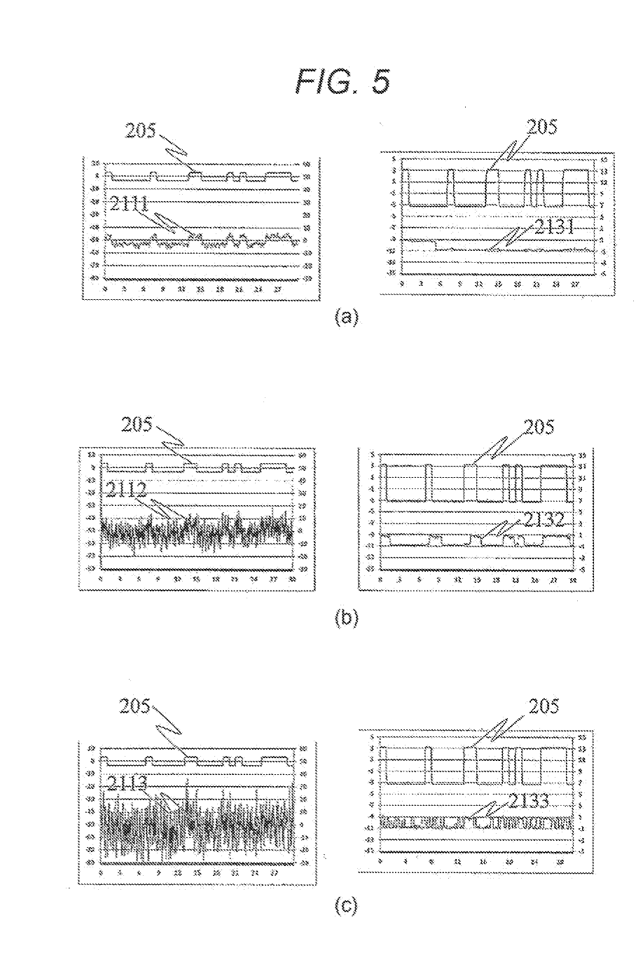

FIGS. 5(a) to 5(c) are results of a signal detection simulation, which is implemented while separating the signal-to-noise ratio into three conditions, in an analog front-end circuit. The SNR is defined by three times of the ratio between the signal level and the noise standard deviation. Here, the signal level is assumed to be 6 V.

In the case of FIG. 5(a), the noise standard deviation is 1.16 V and the SNR is 1.72. In the case of FIG. 5(b), the noise standard deviation is 4 V and the SNR is 0.5. In the case of FIG. 5(c), the noise standard deviation is 9.8 V and the. SNR is 0.2.

In the simulation on three conditions in FIGS. 5(a), 5(b) and 5(c), the random 205 is identical. When the standard deviation of the noise signal 206 varies, input signals formed with noise and signals in an AFE circuit are 2111, 2112 and 2113 respectively. The corresponding output signals (detected signals) are 2131, 2132 and 2133. In a case where the SNR in FIG. 5(a) is large and the SNR in FIG. 5(c) is very small, the error between the input signal and the output signal is large, and the signal detection rate is low. Meanwhile, in the case of SNR=0.5 in FIG. 5(b), the input and output signals are substantially matched, which results in a high detection rate.

This is because the signal detection rate in a bistable system has a strong correlation with signal and noise characteristics and system parameters, especially the values of gain parameters “a” and “b” in equation (1) to cause a stochastic resonance phenomenon.

Moreover, to improve the signal detection rate, optimization setting of the system parameters is necessary according to the input signal. Therefore, in the present embodiment, the parameter control circuit 115 including a system parameter optimization control function is installed as illustrated in FIG. 2. By this means, it is possible to respond to various signals and noise types in various fields and apparatuses, and secure the generality of the present invention.

Although a detailed description is not given here, according to a simulation, by suitable parameter control, the circuit configuration shown in the present embodiment can secure a signal detection rate of 80 percent or more while the SNR is within a range of 0.3 to 1.5. In the case of SNR>1.5, it can be supported in combination with a scheme in the related art.

Thus, in the present invention, as compared with a normal signal processing scheme, the amount of data requiring signal detection is smaller, and it is possible reduce the data processing time. Therefore, the hardware scale necessary for the processing of a large amount of data can also be small. By this means, it is possible to realize the minute signal detection system of the present invention at low cost with power saving.

### Second Embodiment

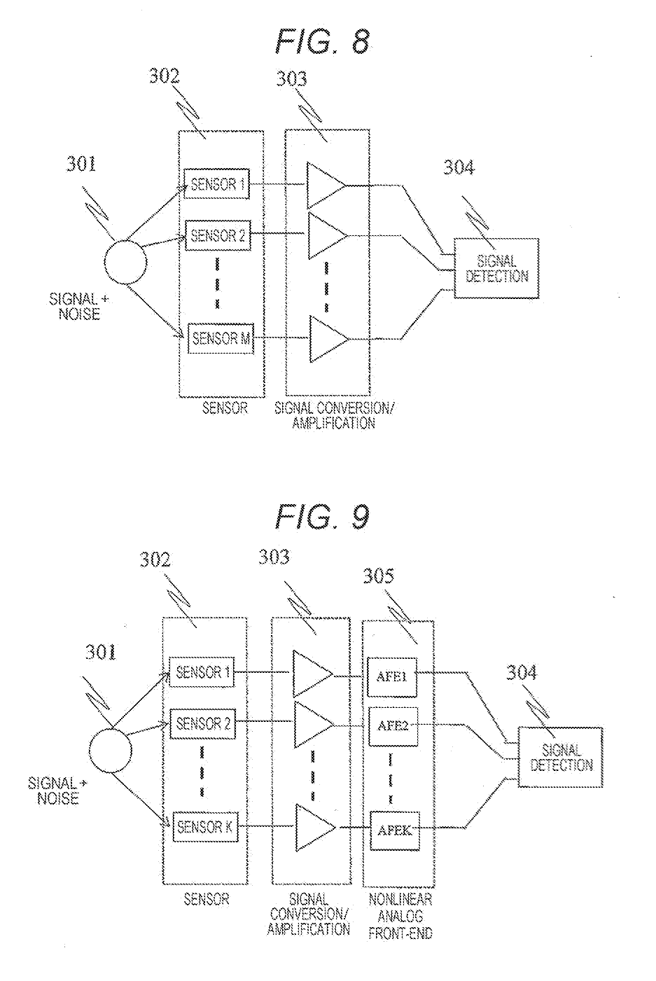

FIG. 8 is a diagram illustrating another configuration of the signal detection system in the related art. In a case where a signal 301 including noise is an asynchronous signal and it is difficult to improve the signal-to-noise ratio by iterative addition along the time axis, this system adopts a configuration to parallelize a sensor 302 and a signal conversion/amplification circuit 303 as a detection circuit and perform detection in a signal detection circuit 304, and improves the SNR.

The improvement rate of the SNR and a necessary parallel number of circuits are in a square relationship, for example, it is necessary to increase a parallel number of detection system circuits by a factor of 16 in order to improve the SNR by a factor of 4, and the circuit size, the cost and the power consumption linearly increase in the second embodiment of the present invention, it is possible to further solve the above-mentioned problem.

FIG. 9 is a diagram illustrating the configuration of the second embodiment of the present invention. The configuration of single part of an analog front-end circuit 305 in the present embodiment is similar to the first embodiment, and detailed explanation about the overlapping parts is omitted.

Although the present embodiment realizes the improvement of the SNR by the same parallel circuit configuration as a scheme in the related art in FIG. 8, it is possible to greatly reduce a necessary parallel number of circuits by using the bistable analog front-end circuit 305. As shown in the simulation in FIGS. 5(a) to 5(c), since it is possible to perform the same signal detection as a normal condition of SNR>2 even in the case of SNR=0.5 by using the analog front-end circuit of the bistable system, there is a quadruple or more effect in the improvement of the SNR. By this means, in the case of the present embodiment, as compared with a circuit scheme in the related art illustrated in FIG. 8, it is possible to reduce the circuit size, the cost and the power consumption by a factor of 10 or more.

### Third Embodiment

In the above-mentioned bistable system, while it is possible to improve the event signal detection rate by optimizing a system parameter according to the SNR of an input signal, the signal detection rate remarkably decreases when the system parameter becomes out of an optimum value.

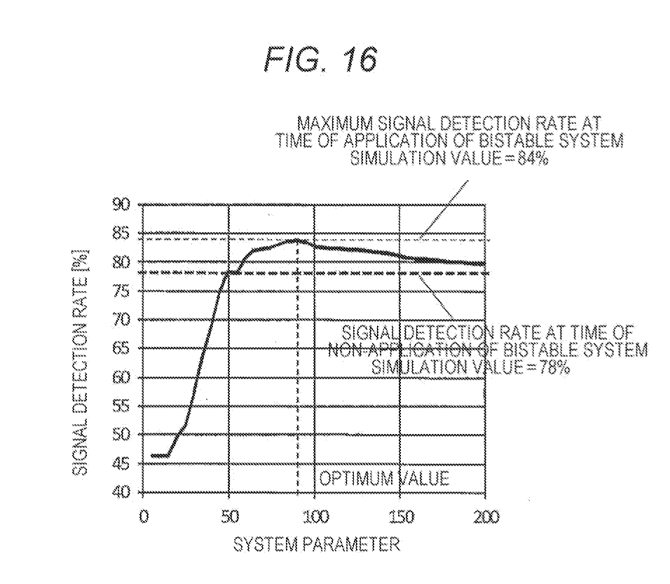

FIG. 16 illustrates the relationship between the system parameter and the signal detection rate. In a case where the system parameter is an optimum value, it is understood that the signal detection rate is improved by applying a bistable system as compared with the time of non-application. Meanwhile, the signal detection rate remarkably decreases when the system parameter becomes out of an optimum value, and the signal detection rate becomes lower than a case where the bistable system is not applied.

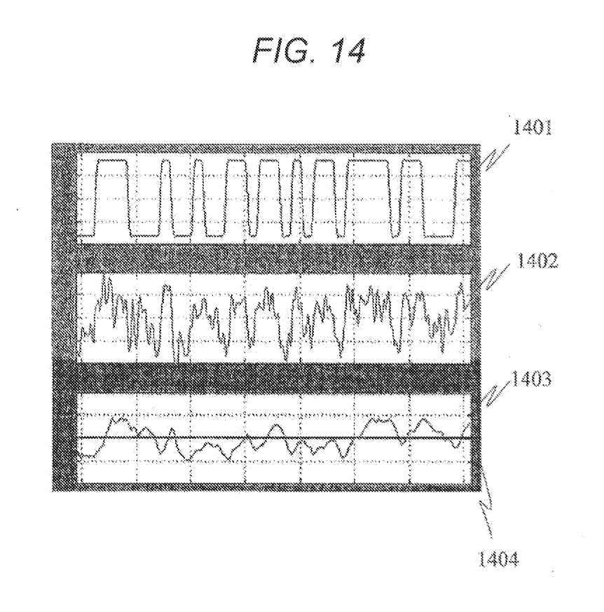

FIG. 14 illustrates a simulation result of minute signal detection of a low signal-to-noise ratio in a case where the system parameter is not optimal in the above-mentioned bistable system. The bistable system generates an output signal 1403 from an input, signal 1402 which is acquired by superposing random noise on an event signal 1401, through an integration circuit, an amplification circuit, a tertiary-square circuit and an addition circuit. In a case where the system parameter is not optimal, especially in a case where the feedback amount is smaller than the optimum value, the rise/fall time of the output signal 1403 becomes slow, it is not possible to exceed a symbol determination level 1404 for signal detection determination, and the signal detection rate decreases as compared with a case where the bistable system is not applied. Although it is possible to optimize the system parameter by the above-mentioned parameter control circuit, in the case of a system in which the level of random noise changes over time, since it is necessary to optimize the system parameter according to the level of the random noise, there is a possibility that the apparatus throughput decreases.

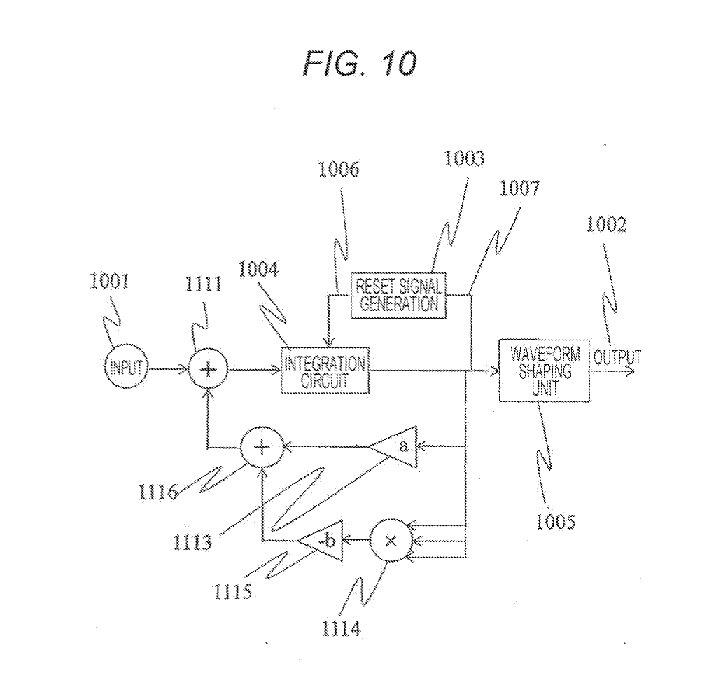

FIG. 10 illustrates a circuit configuration of an advanced bistable system that solves such a problem. The advanced bistable system is characterized in including, in the above-mentioned bistable system, an integration circuit 1004 with reset that resets an integration value when a reset signal 1006 is input, a reset signal generation unit 1003 that generates the reset signal 1006 from an integration signal 1007 output from the integration circuit 1004 with reset, and a signal shaping unit 1005 that shapes and outputs the integration signal 1007.

The reset signal generation unit 1003 is configured to output the reset signal 1006 to the integration circuit 1004 with reset in a case where a predetermined value is exceeded in the integration signal 1006 output from the integration circuit 1004 with reset. Moreover, the signal shaping unit 1005 is a block that shapes the integration signal 1007 to a rectangular wave signal.

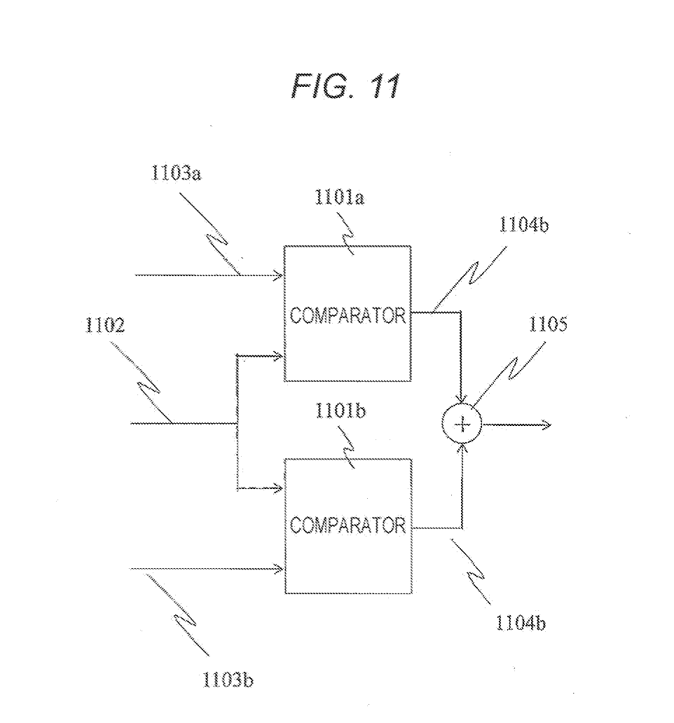

FIG. 11 illustrates one example of a circuit configuration of a reset signal generation unit. The reset signal generation unit is formed with: a comparator 1101a that receives an integration signal 1102 and a threshold 1103a as input, signals and outputs a reset signal 1104a in a case where the integration signal 1102 is lower than the threshold 1103a; a comparator 1101b that receives the integration signal 1102 and a threshold 1103b as input signals and outputs a reset signal 1104b in a case where the integration signal 1102 is higher than the threshold 1103b; and an addition circuit 1105 that adds the reset signals 1104a and 1104b output from the comparators 1101a and 1101b and outputs the result.

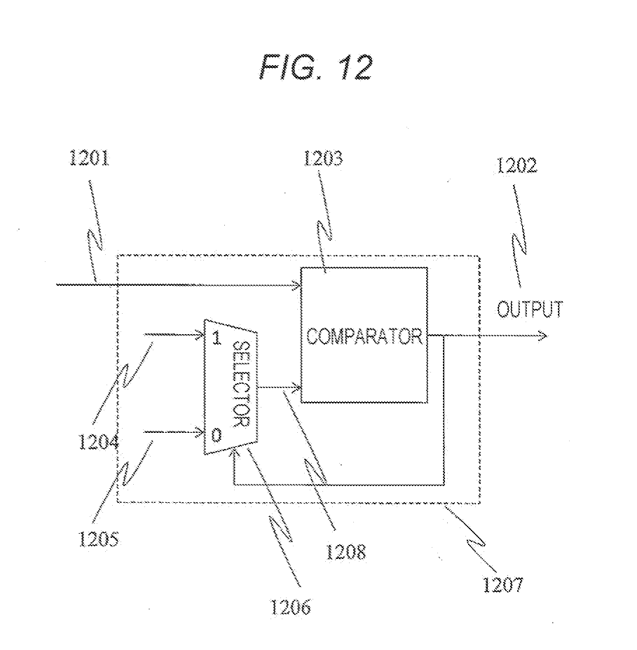

FIG. 12 illustrates one example of a circuit configuration of a signal shaping unit. A signal shaping unit 1207 is formed with: a comparator 1203 that receives an integration signal 1201 and a selector output signal 1208 as input signals, outputs 1 in a case where the integration signal 1201 is higher than the selector output signal 1208, and outputs 0 in a case where the integration signal 1201 is lower than the selector output signal 1208; and a selector 1206 that switches and outputs two input signals 1204 and 1205 according to an output signal 1202 of the comparator 1203. This circuit is a circuit generally called “Schmitt trigger circuit”, and is characterized in having a hysteresis property in which the symbol determination level for signal symbol determination switches according to the symbol of the output signal 1202 of the comparator 1203.

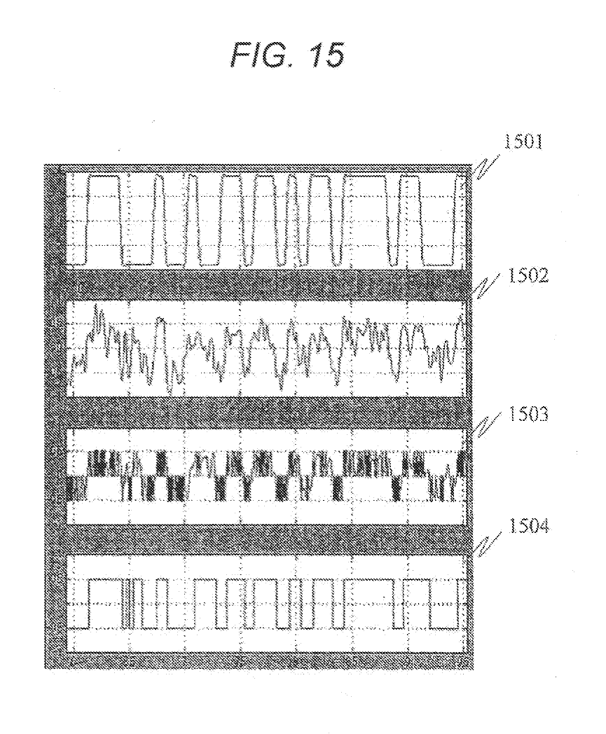

FIG. 15 illustrates the simulation results of minute signal detection of a low signal-to-noise ratio in a case where the advanced bistable system is applied. An input signal 1502 superposing random noise on an event signal 1501 becomes an integration signal 1503 through a feedback circuit formed with an integration circuit with reset, an amplification circuit and a multiplication circuit. The integration signal 1503 is signal-shaped by a signal shaping unit and output as an output signal 1504. Since it is possible to equivalently fasten the rise/fall time of the integration signal by the integration circuit with reset and the signal shaping unit, it possible to improve the event signal detection rate even in a case where the system parameter is not optimal. According to the present embodiment, since it is possible to improve the signal detection rate even in a case where the system parameter is not optimal, it is possible to detect a minute signal without decreasing the apparatus throughput even in a system in which the level, of random noise changes over time.

### Fourth Embodiment

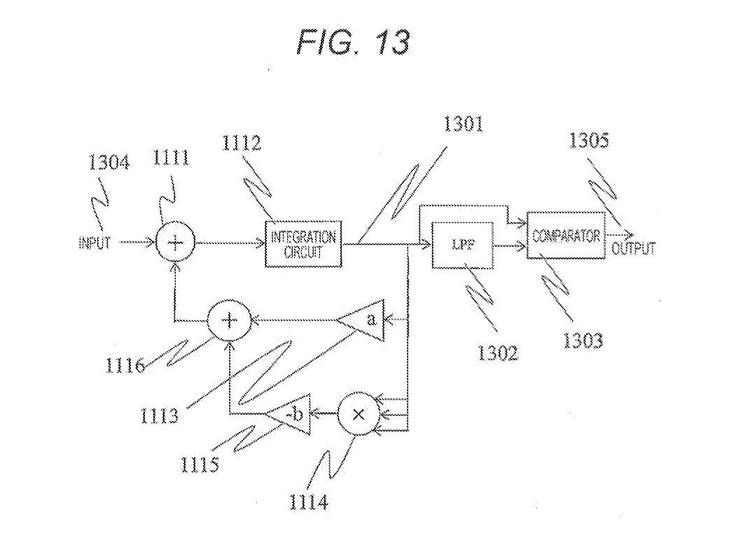

FIG. 13 illustrates another embodiment of the advanced bistable system. In the present embodiment, it is formed with a low-pass filter 1302 that causes the lower frequency element of an integration signal 1301 output from the integration circuit 1112 to pass, and a comparator 1303 that receives the integration signal 1301 and the output signal of the low-pass filter 1302 as input and evaluates their magnitude.

As described above, in a case where the system parameter is not optimal in the bistable system, the rise/fall time of the integration signal 1301 slows, the symbol determination level for signal detection determination is not exceeded and the signal detection rate decreases. In the present embodiment, by using the output of the low-pass filter 1303 for the symbol determination level of signal detection determination, the rise/fall time of the integration signal 1301 is equivalently fastened.

Therefore, by not only the low-pass filter but also a circuit having a function to determine the symbol determination level from the integration signal 1301 or something that can equivalently fasten the rise/fall time of the integration signal 1301, it is possible to acquire a similar effect.

Embodiments of the present invention have been described above in detail. However, the specific examples described in the specification are merely the typical ones, and the scope and spirit of the present invention are shown in the following claims. Moreover, various modes can be formed by arbitrary combinations of multiple components disclosed in the embodiments. Further, control lines and information lines considered to be necessary for explanation are shown in the above-mentioned embodiments, and all control lines and information lines on products are not necessarily shown. All components may be mutually connected. Additionally, for persons who have general knowledge of this technical field, other implementations of the present invention are clear from consideration of the specification and embodiments of the present invention disclosed herein.

### REFERENCE SIGNS LIST

101 signal conversion/amplification circuit
102, 112 analog-to-digital conversion circuit
103, 113 data transfer circuit
104, 114 digital signal processing circuit
115 parameter control circuit
111 nonlinear analog front-end circuit (AFE)
1111, 1116 addition circuit in bistable analog front-end
1112 integration circuit in bistable analog front-end
1113, 1115 amplification circuit in bistable analog front-end
1114 multiplication circuit in bistable analog front-end
201 input signal (noise and signal embedded in noise)
202 input signal processed in signal conversion/amplification circuit 101 (input signal transmitted to detection system)
203 detected signal
204 intermediate result of signal detection in the first embodiment of present invention
205 signal for simulation in the first embodiment of present invention
206 noise for simulation in the first embodiment of present invention
211, 2111, 2112, 2113 input signal of analog front-end circuit in the first embodiment of present invention
213, 2131, 2132, 2132 output signal of analog front-end circuit in the first embodiment of present invention
301 sum of signal and noise in the second embodiment of present invention
302 detection sensor of physical signal in the second embodiment of present invention
303 signal conversion and amplification circuit in the second embodiment of present invention
304 signal detection processing circuitry in the second embodiment of present invention
305 analog front-end circuit in the second embodiment of present invention
1001, 1304 input signal of bistable system
1002, 1202, 1305 output signal of bistable system
1003 reset signal generation unit
1004 integration circuit with reset
1005, 1207 waveform shaping unit
1006, 1104a, 1104b reset signal
1007, 1102, 1201, 1301 integration signal
1101a, 1101b, 1203, 1303 comparator
1103a, 1103b threshold value
1105 addition circuit
1204, 1205 input signal of selector
1206 selector
1208 output signal of selector
1302 low-pass filter
1401, 1501 event signal
1402, 1502 input signal bistable system, which superposes random noise on event signal
1403 output signal of bistable system when system parameter is not optimal
1404 symbol determination level for signal detection determination
1503 integration signal of advanced bistable system
1504 output signal of advanced bistable system

1. A minute signal detection system comprising:
a circuit which converts and amplifies an input signal;
a nonlinear analog front-end circuit which determines an existence/nonexistence of a minute signal from the input signal converted and amplified by the amplification circuit and which outputs information on the existence/nonexistence of the minute signal as an event signal;
an analog-to-digital conversion circuit which drives
operation mode control based on the event signal output by the nonlinear analog front-end circuit and performs analog-to-digital conversion on the converted, amplified input signal;
a data transfer circuit which drives the operation mode control by the event signal and transfers the signal subjected to the analog-to-digital conversion;
a digital signal processing circuit which drives the operation mode control by the event signal and performs digital signal processing on the signal transmitted from the data transfer circuit and detects the signal; and
a parameter control circuit which controls a characteristic parameter of the nonlinear analog front-end circuit according to characteristics of the minute signal and a noise.

2. The minute signal detection system according to claim 1, wherein the nonlinear analog front-end circuit is a circuit including:
An integration circuit which integrates the input signal;
An amplification circuit which amplifies an output signal of the integration circuit by a constant gain;
A multiplication circuit which tertiary-squares an output signal of the integration circuit;
An amplification and phase inversion circuit which amplifies and phase-inverts the tertiary-squared signal;
A circuit which adds the amplified signal and the amplified, phase-inverted signal; and
an addition circuit which adds the added signal and the input signal.

3. The minute signal detection system according to claim 1, wherein multiple sets of the signal conversion/amplification circuit and the nonlinear analog front-end circuit connected with the signal conversion/amplification circuit are included and connected in parallel.

4. The minute signal detection system according to claim 1, wherein the nonlinear analog front-end circuit is a circuit including:
an integration circuit which integrates an input signal and can reset an integration value by a reset signal;
a reset signal generation circuit which generates the reset signal from the integration signal;
an amplification circuit which amplifies the integrated signal;
a multiplication circuit which tertiary-squares the integrated signal;
an amplification and phase inversion circuit which amplifies and phase-inverts the tertiary-squared signal;
a circuit which adds the amplified signal and the amplified, phase-inverted signal;
an addition circuit which adds the added signal and the input signal; and
a signal shaping circuit which shapes the integrated signal into a rectangular waveform.

5. The minute signal detection system according to claim 4, wherein the reset signal generation circuit is a circuit including:
a comparator which receives the integrated signal and an arbitrary threshold as input signals and outputs the reset signal in a case where the integrated signal is smaller than the threshold;
a comparator which receives the integrated signal and a different threshold from the arbitrary threshold as input signals and outputs the reset signal in a case where the integrated signal is larger than the threshold; and
an addition circuit which adds and outputs the reset signals output from the comparators.

6. The minute signal detection system according to claim 1, wherein the nonlinear analog front-end circuit is a circuit including:
an integration circuit which integrates the input signal;
an amplification circuit which amplifies the integrated signal;
a multiplication circuit which tertiary-squares the integrated signal;
an amplification and phase inversion circuit which amplifies and phase-inverts the tertiary-squared signal;
a circuit which adds the amplified signal and the amplified, phase-inverted signal;
and an addition circuit which adds the added signal and the input signal; and
a symbol determination level generation circuit which decides a symbol determination level from the integrated signal; and
a comparator which compares the integrated signal and the symbol determination level.

7. The minute signal detection system according to claim 6, wherein the symbol determination level generation circuit includes a low-pass filter.

8. A minute signal detection method comprising:
a step of converting and amplifying an input signal;
a step of determining an existence/nonexistence of a minute signal from the converted, amplified input signal;
a step of converting the converted, amplified input signal from an analog signal into a digital signal based on information on the existence/nonexistence of the minute signal; and
a step of performing signal processing on the converted digital signal and separating and detecting a valid signal from the minute signal including noise.

9. The minute signal detection method according to claim 8, wherein the step of determining the existence/nonexistence of the minute signal from the converted, amplified input signal includes:
a step of integrating the converted, amplified input signal;
a step of amplifying the integrated signal by a constant gain;
a step of third-squaring the integrated signal;
an amplification and phase inversion circuit which amplifies and phase-inverts the tertiary-squared signal;
a step of adding the signal amplified by the constant gain and the amplified, phase-inverted signal; and
an addition step of adding the added signal and the input signal.
